(19) United States
(12) Patent Application Publication
(10) Pub. No.: US 2011/0207297 A1
(43) Pub. Date: Aug. 25, 2011

(54) Method for Manufacturing Chalcopyrite Film

(75) Inventors: Kiyoshi Yaginuma, Tokyo (JP); Takashi Minemoto, Kusatsu-shi (JP); Keiji Tsutsumi, Kusatsu-shi (JP)

(73) Assignees: SUMITOMO METAL MINING CO., LTD., Tokyo (JP); THE RITSUMEIKAN TRUST, Kyoto (JP)

(21) Appl. No.: 13/030,304

(22) Filed: Feb. 18, 2011

(30) Foreign Application Priority Data
Feb. 19, 2010 (JP) 2010-035330

(51) Int. Cl. H01L 21/20

(52) U.S. Cl. 438/478; 257/E21.09

(57) ABSTRACT

A highly safe method of obtaining chalcopyrite film wherein a Ib group metal and IIIb group metal are sufficiently combined with a VIb group element by only heat treatment without using an atmosphere containing a VIb group element (Se, S, Te).

A chalcopyrite film 10 made of a Ib-IIIb-VIb group compound is formed on a bottom electrode 3 that is formed on a substrate 2, by forming a precursor film 7 that includes a Ib group metal and a IIIb group metal on the bottom electrode 3 beforehand, depositing a VIb group element 9 on the precursor film 7, placing a cover 8 over the precursor film 7 on which the VIb group element 9 has been deposited, and with the Ib group metal, IIIb group metal and VIb group element between the bottom electrode 3 and cover 8, heat treatment is performed in an inert atmosphere to combine the Ib group metal and IIIb group metal with the VIb group element.

### TECHNICAL FIELD

The present invention relates to a method for manufacturing chalcopyrite film that is made of a Ib-IIIb-VIb group compound and used for the light-absorbing layer of CIS type solar batteries, and more particularly to a method for manufacturing chalcopyrite film by chemically combining a Ib group metal and a IIIb group metal in a precursor film with a VIb group element.

### RELATED ART

In an attempt to prevent global warming, there has a been a trend in recent years to conserve energy, which has brought about an increase in interest in photovoltaic power generation that uses light energy such as from the sun. Due to differences in element shapes and materials used for light absorbing layers, there are various types of solar batteries that are used in photovoltaic power generation, and research and development of each is advancing.

Of these, solar batteries that use a Ib-IIIb-VIb group compound called a chalcopyrite type compound (CIS compound), also called CIS type solar batteries, have gained much attention recently. CIS type solar batteries are a thin-film type of solar battery, having an advantage in that CIS type solar batteries use less semiconductor material in the formation of the battery, and having high energy conversion efficiency, are in the stage of becoming practical.

FIG. 3 illustrates typical construction of a CIS type solar battery. The CIS type solar battery 1 has a layered structure, with a bottom electrode 3 made from a molybdenum metal film, a light absorption layer 4 comprising a chalcopyrite film made of a Ib-IIIb-VIb group compound, a buffer layer 5 made of a cadmium sulfide (CdS) film and a transparent electrode layer 6 made of a zinc oxide (ZnO) film being layered in order on a substrate 2 made of soda-lime glass.

Copper (Cu), silver (Ag) or the like is normally used as the Ib group metal, indium (In), gallium (Ga), aluminum (Al) or the like is used as the IIIb group metal and selenium (Se), sulfur (S), tellurium (Te) or the like is used as the VIb group element.

Of the manufacturing processes for manufacturing a CIS type solar battery having this kind of structure, the process of manufacturing a chalcopyrite film that forms the light-absorption layer 4 and has a large effect on the energy conversion efficiency of the solar battery is the most important. The chalcopyrite film is typically obtained by forming a precursor film made of a Ib-IIIb group metal alloy on the bottom electrode 3 that is formed on the substrate 2 by a sputtering method, and then combining the Ib group metal and IIIb group metal in the precursor film with the VIb group element.

As disclosed in Patent Documents 1 to 3, this combination process is performed by heating the precursor film at a temperature of about 500° C. in an atmosphere containing a VIb group element such as H₂Se gas, Se gas, H₂S, S gas or the like.

However, gasses containing VIb group elements have strong toxicity, so it is necessary to take sufficient measures such as preventing gas leakage from the reaction vessel in order to maintain safety. Moreover, there is a problem in that such gasses are expensive, and because it is necessary to constantly supply the gas during the combination reaction, cost increases.

On the other hand, in Patent Document 4, a method is disclosed in which after forming a Cu—In layer on a conductive substrate, that layer and substrate are immersed in a selenium colloid solution to form a Se layer by causing Se to adhere to the surface of the Cu—In layer, then heat treatment is performed to form a chalcopyrite film made of a Cu—In—Se ternary alloy.

In this case, it is not necessary to supply Se gas, however, the colloid solution adheres to the entire immersed object, so there is a problem in that Se adheres to not only the metal film of the Cu—In layer to which Se is supposed to adhere, but also adheres to other parts, and in some cases, there is a possibility that Se will adhere to other apparatuses when conveying the object.

On the other hand, in Patent Document 5, a method is disclosed in which ink, whose main component is seleniumized or sulfurized chalcopyrite nano particles, is coated beforehand onto a Mo electrode by a printing method, after which heat treatment is performed to form a chalcopyrite film. However, in this case, even though the electrode is coated with chalcopyrite type nano particles, the heat treatment after coating must be performed in an atmosphere containing Se or S.

Moreover, in Patent Document 6, a method is disclosed in which after sequentially forming a Se layer or layer containing Se and a copper indium layer using a plating method, heat treatment is performed to form a chalcopyrite film. However, in this case as well, it is necessary to perform heat treatment in an atmosphere containing Se.

In this way, in conventional methods for manufacturing a chalcopyrite film, an atmosphere containing highly toxic and expensive Se or S is used during heat treatment, and a method of forming a chalcopyrite film by sufficiently combining a Ib group metal and IIIb group metal with a VIb group element without using an atmosphere containing a VIb element such as Se or S has not been achieved.

### [Related Art Documents]

### [Patent Documents]

### [Patent Document 1] Japanese Patent No. 3,095,182

### [Patent Document 2] Japanese Patent No. 3,133,136

### [Patent Document 3] Japanese Patent No. 3,249,407

### [Patent Document 4] Japanese Patent No. 3,013,974

### [Patent Document 5] Japanese Patent Application Publication No. 2009-76842

[Patent Document 6] Japanese Patent Application Publication No. H9-321326

### SUMMARY OF THE INVENTION

### Problem to be Solved by the Invention

The object of the present invention is to provide a method for manufacturing a chalcopyrite film that is highly safe and is capable of sufficiently combining a Ib group metal and a IIIb group metal with a VIb group element without using an atmosphere containing a VIb group element such as Se, S or Te during the combination process.

### Means for Solving the Problem

The inventor verified the conventional methods for manufacturing a chalcopyrite film, and as a result of diligent examination of methods for sufficiently combining a Ib group metal and IIb group metal in a precursor film with a VIb group element without using an atmosphere containing a VIb group element, completed the present invention.

In other words, the present invention relates to a manufacturing method for manufacturing chalcopyrite film made of a Ib-IIIb-VIb group compound by combing a Ib group metal and a IIIb group metal with a VIb group element by heat treatment on top of a bottom electrode that has been formed on a substrate.

In the present invention, preferably at least one kind from among Cu and Ag is selected and used as the Ib group metal, at least one kind from among In, Ga and Al is selected and used as the IIIb group metal, and at least one kind from Se, S and Te is selected and used as the VIb group element.

Particularly, in the method for manufacturing a chalcopyrite film of the present invention, the Ib group metal, IIIb group metal and VIb group element are located between the bottom electrode that is formed on a substrate and a cover, and then the heat treatment is performed in an inert atmosphere.

More specifically, (1) a precursor film containing the Ib group metal and IIIb group metal is formed beforehand on the bottom electrode, the VIb group element is deposited on the precursor film, the cover is placed over the precursor film on which the VIb group element has been deposited, and then the heat treatment is performed; or (2) a precursor film that includes the Ib group metal and IIIb group metal, and further contains the VIb group element is formed on the bottom electrode, the cover is placed over the precursor film, and then the heat treatment is performed; or (3) a precursor film that includes the Ib group metal and IIIb group metal is formed beforehand on the bottom electrode, the VIb group element is deposited on one surface of the cover, the cover is placed over the precursor film so that the deposited VIb group element faces the precursor film, and then the heat treatment is performed. However, the present invention is not limited to these methods, for example, the invention can also be applied to a method in which chalcopyrite nano particles as disclosed in Patent Document 5 for example that are made of a seleniumized or sulfurized Ib group metal and IIIb group metal are coated on the bottom electrode, so that an Ib group metal, IIIb group metal and VIb group element can be suitably located between the bottom electrode and cover.

The amount of VIb group element is such that the molar number of the VIb group element with respect to the molar number of the Ib group metal and IIIb group metal is from 1.05 to 1.15.

The means for including or depositing the VIb group element is suitably selected from among a sputtering method, vapor deposition method, plating method, electrodeposition method, coating method or spray method.

The expression of the Ib group, IIIb group and VIb group is based on the old IUPAC system, and for reference, in the new IUPAC system, the Ib group corresponds to Group 11, the IIIb group corresponds to Group 13, and the VIb group corresponds to Group 16.

### ADVANTAGES OF THE INVENTION

With the present invention, the Ib group metal, IIIb group metal and VIb group element are covered during heat treatment, so the release of the VIb element into the atmosphere during the combination process is prevented, and it is possible for the combination reaction with the VIb group element to proceed preferentially and effectively. Therefore, it is possible to sufficiently combine the Ib group metal and IIIb group metal with the VIb group element without using an atmosphere having strong toxicity and containing a VIb group element such as Se or S, and thus it is possible to form a chalcopyrite film having excellent crystalline structure.

Furthermore, an atmosphere having strong toxicity and containing a VIb group element is not used, and there is hardly any gas containing a VIb group element generated during heat processing, so in this invention, a sufficiently high level of safety is achieved. Moreover, there is no need to constantly supply gas containing a VIb group element during the combination reaction, and the inert gas that is used during heat treatment is only replaced once in the path and does not need to be supplied constantly, so only a small amount of gas is used, and thus the present invention is also advantageous from the aspect of suppressing manufacturing costs.

### BRIEF DESCRIPTION OF THE DRAWINGS

FIGS. 1A to 1E are process diagrams illustrating two embodiments of the manufacturing process for a chalcopyrite film according to the present invention.

FIG. 2 is a diagram illustrating the measurement results when using an X-ray diffraction apparatus to measure chalcopyrite films obtained in an example of the present invention and in a comparative example.

FIG. 3 is a schematic diagram illustrating one example of the structure of a CIS type solar battery.

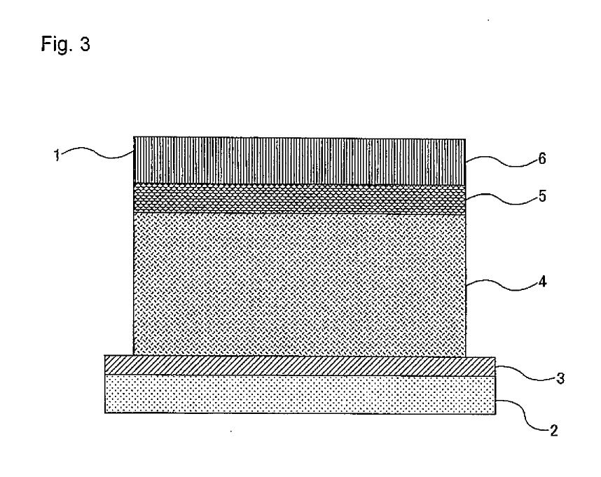

### EMBODIMENTS OF THE PRESENT INVENTION

The inventors verified the conventional manufacturing methods for manufacturing a chalcopyrite film inside an atmosphere containing a VIb group element, however, by this method alone, the atmosphere gas itself that flows along the path for supplying atmosphere gas has toxicity, so it was concluded that improving safety is difficult.

As a method for making it possible to perform heat treatment in an atmosphere that does not contain a VIb group element, the inventors diligently examined methods of depositing a VIb group element on the top of a precursor film, or having a VIb group element be contained in a precursor film beforehand.

However, heating is necessary in order in induce combination with the VIb group element, so by simply depositing the VIb group element on the precursor film or having the precursor film contain the VIb group element beforehand, as the VIb group element reacts with the Ib group metal and IIIb group metal during heating, part of the VIb group element is released into the atmosphere, so it was found that combining the VIb group element does not proceed effectively.

Therefore, the inventors considered that together with depositing a VIb group element on the surface of the precursor film beforehand, or having the precursor film contain a VIb group element beforehand, by using a method in which the VIb group element does not escape into the atmosphere during heating, combination with the VIb group element would proceed in a preferential manner, and thus were able to complete the present invention by finding a way to cover the precursor film during heat treatment.

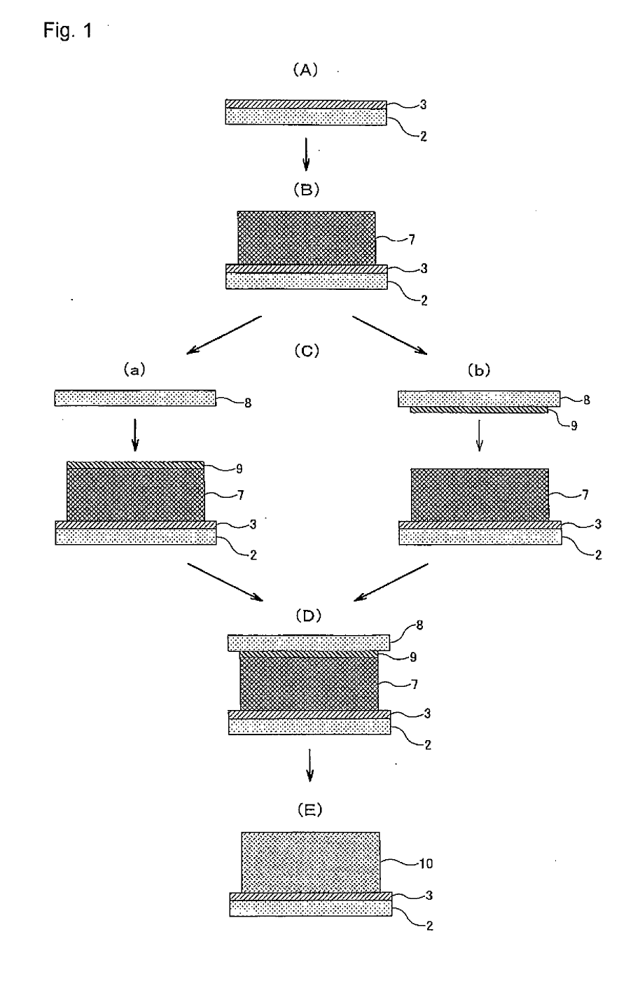

The manufacturing method of a chalcopyrite film of the present invention will be explained in detail with reference to FIGS. 1A to 1E. The following explanation focuses on a manufacturing method comprising a process of depositing a VIb group element on a precursor film, and a manufacturing method comprising a process of depositing a VIb group element on a cover.

First, as illustrated in FIG. 1A and FIG. 1B, a Mo metal film that will become a bottom electrode 3 is formed on the top of a soda-lime glass substrate 2 by using a method such as sputtering, after which a precursor film 7 is formed on the bottom electrode 3 (Mo metal film) by using a method such as sputtering, electrodeposition or plating.

The composition and structure of the precursor film 7, except for the case described later of having the precursor film contain a VIb group element, is not particularly limited as long as the precursor film contains an Ib group metal and a IIIb group metal. For example, the precursor film can be a metal alloy film comprising a Ib group metal and IIIb group metal (for example, a Cu—In alloy film), or can be a layered film having multiple metal layers comprising a Ib group metal and a IIIb group metal (for example a layered film comprising Cu film and In film layers). In the case of forming a metal alloy film, the film can be formed by simultaneously forming an alloy comprising one or more kind of Ib group metal and one or more kind of IIIb group metal, and in the case of forming a layered film, the film can be formed by separately forming films of one or more kind of Ib group metal and one or more kind of IIIb group metal.

The metals of the precursor film are suitably selected from the composition of the CIS type solar battery to be obtained, however, typically, it is possible to use at least one kind selected from among Cu and Ag as the Ib group metal, and to use at least one kind selected from among In and Ga as the IIIb group metal.

It is also preferred that the Ib group metal and the IIIb group metal that are contained in the precursor film be mixed in equimolar ratio, where when Cu is contained as the Ib group metal and both Ga and In are contained as IIIb group metals, it is preferred from the aspect of making the power generation efficiency as high as possible that the mole ratio Cu:Ga:In be 1:0.7:0.3. In the case in which these metals are layered in the form of oxides, it is preferred that these metals be reduced by heating in a reduction atmosphere before depositing the VIb group element. The film thickness of the precursor film 7 is 1 to 8 μm, which is the same as that of a typical film.

After the precursor film 7 is formed on the bottom electrode 3 (Mo metal film), a VIb group element is deposited on the precursor film 7 or on the cover 8, which will be described later and that is used to cover the precursor film 7 during heat treatment, by vacuum vapor deposition or plating to form a VIb group element layer 9. In other words, as illustrated in (a) of FIG. 1C, a VIb group element is deposited on the precursor film 7 to form a VIb group element layer on the precursor film 7, or as illustrated in (b) of FIG. 1C, a VIb group element is deposited on one surface of the cover 8 which is made of a plate such as a soda-lime glass plate, to form a VIb group element layer 9.

The cover 8 should be made of a material that, together with having heat resistance capable of resisting the temperature during heat treatment, has the ability to sufficiently shield the VIb group element without affecting the structure of the precursor film during heat treatment. Examples of such a material are heat-resistant glass plate, or various kinds of heat-resistant ceramic substrates. Preferably the same material as the substrate 2 is used, and when a soda-lime glass plate is used as the substrate 2, a soda-lime glass plate is preferably used as the cover 8.

From the aspect of preventing the VIb group element from escaping into the inert atmosphere during heat treatment, it is necessary that the size (surface area) of the cover 8 be large enough to be able to cover the entire surface of the precursor film 7 (the VIb group element layer 9). The thickness of the cover 8 does not have an essential effect on the advantage of the present invention, however, in the case that the thickness is too thin, the cover could easily break during heating and cooling, and in the case that the thickness is too thick, the cover 8 may become heavy making operation difficult. Depending on the size of the precursor film, when the size is rectangular on the level of several cm, the thickness is preferably about 1 mm, and when a size on the level of several m is desired, a thickness from several mm to 10 mm is preferable from the aspect of handling the cover 8. The shape of the cover 8 is not limited to a plate shape as illustrated in the figure, and any arbitrary shape that is capable of covering the precursor film could be used, however, from the aspect of handling the cover 8, using a plate shape that is the same as the substrate is preferred.

By forming the VIb group element layer 9 on either the precursor film 7 or cover 8, the same effect is obtained when the cover 8 is placed over the precursor film 7. As the method for forming the VIb group element layer 9 on the precursor film 7 or cover 8, in addition to the vacuum vapor deposition method or plating method mentioned above, a method of coating the precursor film 7 with an ink that contains the VIb group element is also an effective method. Furthermore, it is also possible to employ a sputtering method or spray method. Of these various methods, preferably a method is used which is capable of forming a film with a strong adhesive force such that the VIb group element is not scattered to the surroundings. The film formation conditions are the same as in the conventional case, so an explanation is omitted here, however, it is possible for one skilled in the art to select suitable film formation conditions based on various publicly known literature.

As the VIb group element it is possible to use at least one kind of element selected from among Se, S and Te. As the structure of a CIS type solar battery, currently, Cu (In, Ga) Se₂, called CIGS, Cu (In, Ga) (Se, S)₂, called CIGSS, and CuInSe₂, called CIS, are mainstream, with mainly Se and S being used as the VIb group element. However, the structure of a chalcopyrite film is not limited to these, and the present invention widely includes group Ib-IIIb-VIb group compounds that have a structure capable of being used as a CIS solar battery.

The amount (number of moles) of deposited VIb group element, depending on the composition of the formed chalcopyrite film, corresponds to the total of the number of moles of the Ib group metal and IIIb group metal existing in the precursor film 7, with this being the minimum requirement. However, the inventors discovered that for all practical purposes, increasing the amount 10% more than the calculated minimum required number of moles is preferred from the aspect of making the entire chalcopyrite film normal. More specifically, the number of moles of the VIb group element with respect to the sum of the number of moles of the Ib group metal and the IIIb group metal is 1.0 to 2.0, and preferably 1.05 to 1.15. An excess of VIb group element that exceeds the stoichiometric composition evaporates without being taken into the chalcopyrite film, so due to the characteristics of the obtained chalcopyrite film, there is no limit to the upper limit, so from the aspect of being economical and processing the exhaust, keeping the number of mole within the range above is preferred.

After the VIb group element layer 9 has been formed on the precursor film 7, the cover 8 is placed over the precursor film 7 (VIb group element layer 9) as illustrated in (a) of FIG. 1C. On the other hand, when the VIb group element layer 9 is formed on the cover 8, the cover 8 is placed over the precursor film 7 in a direction such that the VIb group element layer 9, which is the surface of the cover 8 where the VIb group element has been deposited, faces the precursor film 7. By doing so, after obtaining the layered object in the state illustrated in FIG. 1D, that layered object is placed in the heating furnace and heat treatment is performed in an inert atmosphere such as argon gas. In doing so, the Ib group metal and IIIb group metal in the precursor film 7 undergo a combining reaction with the VIb group element, to form a chalcopyrite film 10 that comprises a Ib-IIIb-VIb group compound. Particularly, in the case of the present invention, an atmosphere containing a VIb group element such as Se or S is not used in the heat treatment as was done in the conventional methods.

When the heating furnace used is a sealed type, the layered object described above is placed inside the furnace and vacuum degasification is performed, after which an inert gas such as nitrogen or argon is let into the furnace to create an inert gas atmosphere inside the furnace, then the furnace is sealed. Instead of a sealed-type heating furnace, it is also possible to perform heating using a belt furnace, however in that case, in order to maintain an inert state inside the furnace it is necessary to constantly supply the proper amount of inert gas.

The heating temperature is no less than 300° C. and no greater than 650° C., and preferably is set so that the peak temperature is no less than 400° C. and no greater than 550° C., and it is necessary that the peak temperature be maintained for 3 minutes or more. When the heating temperature is less than 300° C., formation of the chalcopyrite film is insufficient, and when the heating temperature exceeds 650° C., there is no problem with the formation of the chalcopyrite film itself, however, when a soda-lime glass substrate is used as the substrate, there is a problem in that the substrate becomes soft, so is unsuitable. The minimum amount of time that the temperature must be maintained at the peak temperature in order to form the chalcopyrite film is 3 minutes, however maintaining the peak temperature longer than this does not hinder the invention, but from the aspect of keeping cost low, the time should preferably kept short, or more specifically, less than 30 minutes.

After heat treatment is performed as described above, the object is cooled and the cover 8 is removed as illustrated in FIG. 1E.

With the manufacturing method of the present invention, comprising the processing steps described above, the cover is able to effectively prevent VIb group element from being released into the atmosphere, and thus the combination reaction with the VIb group element can advance effectively. Therefore, it is possible to sufficiently combine the Ib group metal and IIIb group metal in the precursor film with a VIb group metal even without using an atmosphere containing a VIb group metal such as Se and S, and so it is possible to form a proper chalcopyrite film having excellent crystalline structure.

Furthermore, during heat treatment, most of the occurrence of gas including the VIb group element is eliminated, so a highly safe manufacturing method is provided. Moreover, the inert gas such as nitrogen gas or argon gas only needs to be introduced once along the path, so it is possible to form a chalcopyrite film having good crystalline structure without having to constantly supply gas during the combination reaction, thus only a small amount of gas needs to be used, which is advantageous from the aspect of keeping down the cost of manufacturing chalcopyrite film.

The explanation above was for the case in which a VIb group element was deposited on either a precursor film or a cover, however, the present invention can also be embodied by performing a process of forming a precursor film that contains a VIb group element beforehand on the bottom electrode instead of this process of depositing the VIb group element. As a method of including the VIb group element inside the precursor film in this way, a precursor film containing a VIb group element can be formed by, forming a film made of a Ib group metal or IIIb group metal and containing a VIb group element (for example a Cu—Se film, or In—Se film) on the bottom electrode by sputtering or the like, or by forming powdered or colloidal type VIb group element together with the Ib group metal or IIIb group metal on the bottom electrode by plating. In addition to this, it is also possible to form a precursor film that contains a VIb group element by using an evaporation deposition method, coating method, or spraying method. Furthermore, the invention can also be applied when chalcopyrite nano particles comprising a seleniumized or sulfurized Ib group metal and IIIb group metal is coated on the bottom electrode.

In either case, after a precursor film containing a VIb group element has been formed, it is possible to form a chalcopyrite film going through the processes illustrated in (a) of FIG. 1C→FIG. 1D→FIG. 1E in the same was as in the case when a VIb group element is deposited on the precursor film. In the case where a VIb group element is contained in the precursor film in this way, it is also possible to obtain the same effect as when a VIb group element is deposited on the precursor film.

### EXAMPLES

### Example 1

First, masking was performed on the edge sections of a 25.4 mm (1 inch) square and 2 mm thick soda-lime glass substrate (manufactured by Matsunami Glass Ind., Ltd.), after which a sputtering apparatus (SPF-312, manufactured by Canon ANELVA Corporation) was used to form a 20 mm square copper gallium alloy metal film using an alloy target with a Cu:Ga mole ratio of 1.0:0.3 by sputtering, then on that formed copper gallium alloy film a metal indium film was formed using an indium target so that the Cu:Ga:In mole ratio became 1:0.7:0.3. In this way, a 20 mm square Cu—Ga—In precursor film having an overall thickness of approximately 1.5 μm was formed. In the sputtering method, the film formation conditions were set so that the composition of the film is the same that of the target.

Next, Se was deposited on the obtained precursor film by resistance heating vacuum vapor deposition using a vacuum deposition apparatus (EBH-6, manufactured by ULVAC, Inc.). The amount of vapor deposition of Se is set by calculating the number of Se moles necessary for combination to chalcopyrite based on the number of moles of Cu—Ga—In metal in the precursor film, so that the amount is 10% greater than the calculated amount, or more specifically is set such that the mole ratio of (Cu+Ga+In):Se is 1:1, and such that the thickness of the Se film becomes 2 μm.

After Se has been deposited, a 25.4 mm square soda-lime glass substrate having a thickness of 2 mm that is the same as the substrate described above is placed over the Se film.

Next, the sample on which the Se film has been formed is placed inside a sealed-type heating furnace (MLA-3000, manufactured by ULVAC, Inc.), and after the inside of the furnace was put into a vacuum state using a rotary pump, nitrogen gas was introduced into the furnace. At the point when the pressure reached ambient pressure, the furnace was sealed. The sample was then heated to 550° C. for 10 minutes, and maintained at 550° C. for 30 minutes. After that, the electric power to the heater was turned OFF, and the sample was allowed to cool for 30 minutes or more until it reached ambient temperature.

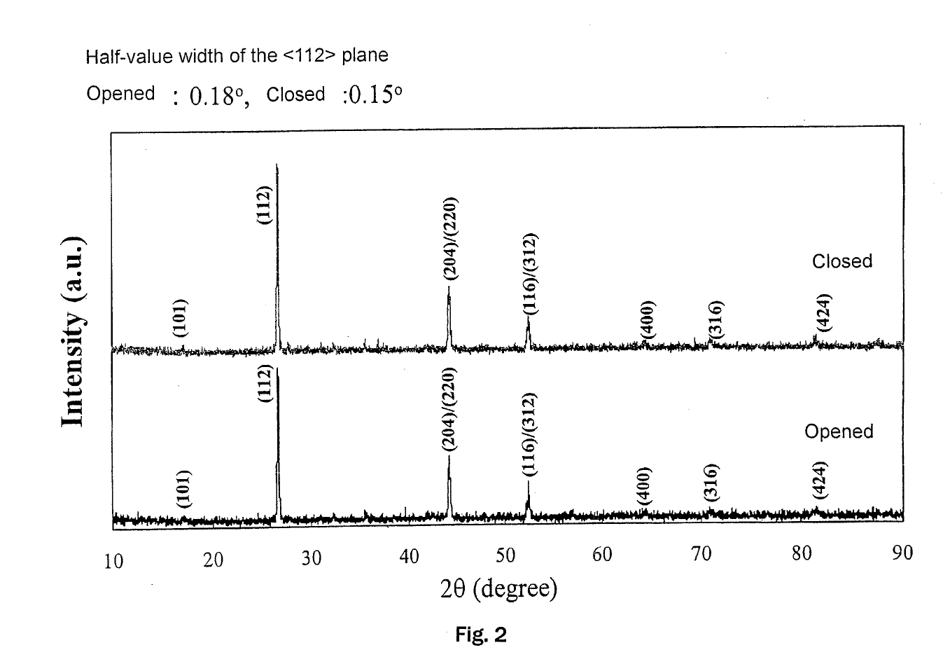

After that, the cover was removed from the sample and the chemical composition of the film formed on the soda-lime substrate was measured using an energy dispersion type X-ray analysis apparatus (EDS; EX-250X-act, manufactured by HORIBA, Ltd.). As a result, the mole ratio was Cu:In:Ga:Se=1.0:0.7:0.3:1.9, and Se/(Cu+In+Ga) was 0.95, so with the composition being nearly the target composition, it could be confirmed that a Cu (In, Ga) Se₂ chalcopyrite film was formed. In addition, using an X-ray diffraction apparatus (XRD; X′ Pert-MRD, manufactured by Spectris Co., Ltd. (PANalytical)), the state of the film formed on the glass substrate was confirmed. The diffraction peaks obtained from the X-ray diffraction apparatus are illustrated by the top graph in FIG. 2. The obtained diffraction peaks match all of the crystallographic data for chalcopyrite, and indicate that single-phase Cu (In, Ga) Se₂ with no different phases was obtained. The half-value width of the <112> plane of the main orientation of CIGS was 0.15 degrees. This value is very close to the 0.14 of the half-value width of a high-quality CIGS film that is formed by vapor deposition, so it could be confirmed that chalcopyrite film having good crystalline structure was formed.

In the method for manufacturing a chalcopyrite film of this example described above, there was no need for continuous gas flow during the combination reaction as was necessary in the conventional methods that used an atmosphere containing a VIb group element such as H₂Se, and because an effective reaction with Se is possible, safety is excellent. After the test, a small amount of Se was deposited on the walls of the heating furnace as a solid, however, the removal was easier and safer than handling a gas.

### Comparative Example

Except for not covering the sample with a cover during heat treatment, the chalcopyrite film was formed the same way as in example 1, and measurement was performed in the same way as in example 1.

The measured value of the Se/(Cu+In+Ga) ratio of the obtained chalcopyrite film was 0.85, which was less than the measured value of 0.95 in example 1. Moreover, the diffraction peaks that were obtained using an X-ray diffraction apparatus were as illustrated by the bottom graph in FIG. 2, with the half-value width of the <112> plane of the main orientation of CIGS being 0.18 degrees, which is clearly greater than the 0.15 degrees in example 1 (case with a cover). This indicates that the combination reaction with Se was inferior when compared with that in example 1, so the crystalline structure of the chalcopyrite film of comparative example 1 became worse.

### Example 2

Except for using S instead of Se as the VIb group element, the chalcopyrite film was formed in the same way as in example 1.

In the chemical composition of the obtained chalcopyrite film, the mole ratio of Cu:In:Ga:S=1.0:0.7:0.3:1.9, and S/(Cu+In+Ga) was 0.95, so it could be confirmed that a film having nearly the target composition was obtained. Moreover, the state of the film was checked using an X-ray diffraction apparatus, and it was found that the obtained diffraction peaks matched all of the crystallographic data for chalcopyrite, so it was confirmed that single-phase Cu (In, Ga) S₂ with no different phases was obtained. The half-value width of the <112> plane of the main orientation was 0.15 degrees, so it was confirmed that a good crystalline structure was obtained.

### Example 3

Except for using Te instead of Se as the VIb group element, the chalcopyrite film was formed in the same way as in example 1.

In the chemical composition of the obtained chalcopyrite film, the mole ratio of Cu:In:Ga:Te=1.0:0.7:0.3:1.9, and Te/(Cu+In+Ga) was 0.95, so it could be confirmed that a film having nearly the target composition was obtained. Moreover, the state of the film was checked using an X-ray diffraction apparatus, and it was found that the obtained diffraction peaks matched all of the crystallographic data for chalcopyrite, so it was confirmed that single-phase Cu (In, Ga) Te₂ with no different phases was obtained. The half-value width of the <112> plane of the main orientation was 0.14 degrees, so it was confirmed that a good crystalline structure was obtained.

### Explanation of Reference Numbers

1 CSI type solar battery

2 Substrate

3 Bottom electrode

4 Light absorption layer

5 Buffer layer

6 Transparent electrode layer

7 Precursor film

8 Cover

9 VIb group element layer

10 Chalcopyrite film

What is claimed is:

1. A method for manufacturing a chalcopyrite film made of a Ib-IIIb-VIb group compound by combing a Ib group metal and IIIb group metal with a VIb group element by heat treatment on top of a bottom electrode that has been formed on a substrate,
the heat treatment being performed by heat-treating the Ib group metal, IIIb group metal and VIb group element in an inert atmosphere under a situation where they are located between the bottom electrode that is formed on a substrate and a cover.

2. The method for manufacturing a chalcopyrite film according to claim 1, wherein the method comprises the steps of: forming a precursor film containing the Ib group metal and IIIb group metal beforehand on the bottom electrode; depositing the VIb group element on the precursor film; placing the cover over the precursor film on which the VIb group element has been deposited; and then performing the heat treatment.

3. The method for manufacturing a chalcopyrite film according to claim 1, wherein the method comprises the steps of: forming a precursor film that includes the Ib group metal and IIIb group metal, and further contains the VIb group element on the bottom electrode; placing the cover over the precursor film; and then performing the heat treatment.

4. The method for manufacturing a chalcopyrite film according to claim 1, wherein the method comprises the steps of: forming a precursor film that includes the Ib group metal and IIIb group metal beforehand on the bottom electrode; depositing the VIb group element on one surface of the cover; placing the cover over the precursor film so that the deposited VIb group element faces the precursor film; and then performing the heat treatment.

5. The method for manufacturing a chalcopyrite film according to claim 1, wherein the means for including or depositing the VIb group element is suitably selected from among a sputtering method, vapor deposition method, plating method, electrodeposition method, coating method or spray method.

6. The method for manufacturing a chalcopyrite film according to claim 1, wherein the amount of VIb group element is decided such that the molar number of VIb group element with respect to the molar number of Ib group metal and IIIb group metal is from 1.05 to 1.15.

7. The method for manufacturing a chalcopyrite film according to claim 1, wherein at least one kind from among Cu and Ag is selected and used as the Ib group metal, at least one kind from among In, Ga and Al is selected and used as the IIIb group metal, and at least one kind from Se, S and Te is selected and used as the VIb group element.
